(19) United States
(12) Patent Application Publication
(10) Pub. No.: US 2025/0107335 A1
(43) Pub. Date: Mar. 27, 2025

(54) DISPLAY PANELS AND DISPLAY DEVICES

(71) Applicant: WUHAN CHINA STAR OPTOELECTRONICS SEMICONDUCTOR DISPLAY TECHNOLOGY CO., LTD., Wuhan, Hubei (CN)

(72) Inventors: Jian ZENG, Wuhan, Hubei (CN); Haitao XU, Wuhan, Hubei (CN); Can HUANG, Wuhan, Hubei (CN); Wenxu XIANYU, Wuhan, Hubei (CN)

(21) Appl. No.: 18/558,917

(22) PCT Filed: Jun. 30, 2023
(86) PCT No.: PCT/CN2023/104662

§ 371 Date: Nov. 3, 2023

(30) Foreign Application Priority Data
Nov. 30, 2022 (CN) 202211523097.5

(51) Int. Cl. H10K 59/122; H10K 59/80

(52) U.S. Cl. CPC H10K 59/122; H10K 59/873

(57) ABSTRACT

Disclosed are a display panel and a display device, the display panel includes a substrate, a pixel definition layer, a light-emitting device layer, and an encapsulation layer. The pixel definition layer includes a first groove and a second groove. The light-emitting device layer includes a common functional layer. The encapsulation layer includes a first encapsulation sublayer. A protrusion is provided at an opening of the second groove. The common functional layer is disconnected at the second groove. The first encapsulation sublayer is continuous at the second groove. A protruding distance of the protrusion is less than or equal to one tenth of the thickness of the first encapsulation sublayer.

### TECHNICAL FIELD

The present disclosure relates to a field of display technologies, and more particularly, to display panels and display devices.

### BACKGROUND

With the development of display technology, an organic light emitting diode (OLED) is gradually becoming the mainstream in the display field due to its excellent properties such as self-luminescence, high contrast, wide viewing angle, low power consumption, and bendable. An OLED device in an OLED display panel is composed of an anode, a light-emitting device layer, and a cathode. Some of film layers in the light-emitting device layer are common functional layers formed by evaporation via an open mask. In this way, the use of fine metal masks (FMM) can be reduced, thereby saving the production cost. However, a lateral leakage current between adjacent pixels may occur inevitably in such common functional layers, resulting in a problem of accidental luminescence of pixels, and thus affecting the display effect of an image.

### SUMMARY

At present, a number of means have been proposed to solve the problem of the accidental luminescence of pixels. For example, a certain number of convex spacers are provided between the pixels to partially block the common functional layer between the pixels, thereby reducing the lateral leakage current to achieve the purpose of solving the accidental luminescence of pixels. However, such convex spacers increase the risk of scratch, and generate foreign matter particles so as to cause the encapsulation failure. At the same time, the convex spacers also deteriorate the leveling of the organic film layer in the encapsulation layer and affect the encapsulation effect. In addition, a number of grooves may be provided in the pixel definition layer between the pixels to partially block the common functional layer between the pixels. However, the preparation of the grooves requires a high process requirement. If the groove walls are not steep enough, the common functional layer cannot be effectively blocked. Therefore, in the groove design, in order to further enhance the blocking effect, the present improvement is to provide the groove to have an undercut structure. However, step coverage of an encapsulation layer of upper layers on the undercut structure is very low. Specifically, referring to a region indicated by a circle in FIG. 1, it can be seen that the encapsulation layer has a lower film thickness in the undercut structure region, thereby causing a large risk of encapsulation failure.

Based on the above problems, there is an urgent need to develop a solution that can achieve a better encapsulation effect on the basis of improving the problem of the accidental luminescence of pixels.

The present disclosure provides display panels and display devices, the display panels may effectively improve the problem of the accidental luminescence of pixels while ensuring better encapsulation performance.

In order to solve the above problem, according to a first aspect, the present disclosure provides a display panel including a plurality of light-emitting areas spaced apart from each other and a non-light-emitting area between the light-emitting areas, the display panel includes:
A substrate;
A pixel definition layer is disposed on the substrate, and includes one or more first grooves corresponding to the light-emitting areas and one or more second grooves disposed in the non-light-emitting region;
A light-emitting device layer is disposed on the pixel definition layer and the substrate, and includes a light-emitting functional layer and a common functional layer, the light-emitting functional layer is located in the light-emitting areas and the common functional layer is located in the light-emitting areas and the non-light-emitting area;
An encapsulation layer is disposed on the light-emitting device layer and includes a first encapsulation sublayer disposed on the light-emitting device layer, the first encapsulation sublayer is located in the light-emitting areas and the non-light-emitting area;
A protrusion is provided at an opening of each of the second grooves, the common functional layer is disconnected at the second grooves, the first encapsulation sublayer is provided continuously at the second grooves, and a protruding distance of the protrusion is less than or equal to one tenth of a thickness of the first encapsulation sublayer.

According to a second aspect, the present disclosure further provides a display device including the display panel described above, the display panel includes:
A substrate;
A pixel definition layer is disposed on the substrate, and includes one or more first grooves corresponding to the light-emitting areas and one or more second grooves disposed in the non-light-emitting region;
A light-emitting device layer is disposed on the pixel definition layer and the substrate, and includes a light-emitting functional layer and a common functional layer, the light-emitting functional layer is located in the light-emitting areas and the common functional layer is located in the light-emitting areas and the non-light-emitting area;
An encapsulation layer is disposed on the light-emitting device layer and includes a first encapsulation sublayer disposed on the light-emitting device layer, the first encapsulation sublayer is located in the light-emitting areas and the non-light-emitting area;
A protrusion is provided at an opening of each of the second grooves, the common functional layer is disconnected at the second grooves, the first encapsulation sublayer is provided continuously at the second grooves, and a protruding distance of the protrusion is less than or equal to one tenth of a thickness of the first encapsulation sublayer.

### DESCRIPTION OF DRAWINGS

FIG. 1 is a scanning electron microscope image of a cross-sectional structure in a display panel in the prior art according to the present disclosure;

FIG. 2 is a schematic plan structural view of a first display panel according to an embodiment of the present disclosure;

FIG. 3 is a schematic cross-sectional view at a position of BB′ in FIG. 2;

FIG. 4 is a schematic cross-sectional structure of a portion of the film layers in the cross-sectional structure provided in FIG. 3;

FIG. 5 is an enlarged schematic view of a region SI in FIG. 4;

FIG. 6 is a scanning electron microscope image of a cross-sectional structure in a display panel according to an embodiment of the present disclosure;

FIG. 7 is a schematic cross-sectional view of a display panel according to an embodiment of the present disclosure;

FIG. 8 is a schematic cross-sectional view of a common functional layer in a display panel according to an embodiment of the present disclosure;

FIG. 9 is a schematic cross-sectional view of a common functional layer in another display panel according to an embodiment of the present disclosure;

FIG. 10 is an enlarged schematic structural view of a region S1 in FIG. 4;

FIG. 11 is a schematic plan structural view of a second display panel according to an embodiment of the present disclosure;

FIG. 12 is a schematic plan structural view of a third display panel according to an embodiment of the present disclosure;

FIG. 13 is a schematic plan structural view of a fourth display panel according to an embodiment of the present disclosure;

FIG. 14 is a schematic plan structural view of a fifth display panel according to an embodiment of the present disclosure;

FIG. 15 is a schematic plan structural view of a sixth display panel according to an embodiment of the present disclosure;

FIG. 16 is a schematic flow diagram of a method for manufacturing a display panel according to an embodiment of the present disclosure; and

FIGS. 17a-17g are schematic diagrams showing processes of a method for manufacturing a display panel according to an embodiment of the present disclosure.

### DETAILED DESCRIPTION

In the description of the present disclosure, it should be understood that orientations or position relationships indicated by the terms “center”, “longitudinal”, “lateral”, “length”, “width”, “thickness”, “upper”, “lower”, “front”, “rear”, “left”, “right”, “vertical”, “horizontal”, “top”, “bottom”, “inside”, “outside”, and the like, are based on orientations or position relationships illustrated in the drawings. The terms are used to facilitate and simplify the description of the present disclosure, rather than indicate or imply that the devices or elements referred to herein are required to have specific orientations or be constructed or operate in the specific orientations. Accordingly, the terms should not be construed as limiting the present disclosure. In addition, the term “first”, “second” are for illustrative purposes only and are not to be construed as indicating or imposing a relative importance or implicitly indicating the number of technical features indicated. Thus, a feature that limited by “first”, “second” may expressly or implicitly include at least one of the features. In the description of the present disclosure, the meaning of “plural” is two or more, unless otherwise specifically defined.

In the present disclosure, the word “exemplary” is used to mean “serving as an example, illustration, or explanation”. Any embodiment described as “exemplary” in the present disclosure is not necessarily construed as being more preferable or advantageous than other embodiments. In order to enable any person skilled in the art to implement and use the present disclosure, the following description is given. In the following description, the details are listed for the purpose of explanation. It should be understood that those of ordinary skill in the art can realize that the present disclosure can also be implemented without using these specific details. In other instances, well-known structures and processes will not be elaborated to avoid unnecessary details to obscure the description of the present disclosure. Therefore, the present disclosure is not intended to be limited to the illustrated embodiments, but is consistent with the widest scope that conforms to the principles and features disclosed in the present disclosure.

An embodiment of the present disclosure provides a display panel, which is described in detail below:

Referring to FIG. 2, the display panel includes a display area including a plurality of light-emitting areas A1 which are arranged at intervals, and a non-light-emitting area A2 which is located between the plurality of light-emitting areas. The light-emitting area A1 is an area that actually emits light when the display panel performs the display, and is used to arrange a light-emitting unit. The non-light-emitting area A2 is an area that remains black when the display panel performs the display, and is used to arrange a circuit for driving the light-emitting unit to emit light, a wiring, and the like. The light-emitting area A1 typically includes a first color light-emitting area A11 for arranging a first color light-emitting unit, a second color light-emitting area A12 for arranging a second color light-emitting unit, and a third color light-emitting area A13 for arranging a third color light-emitting unit. Typically, the first color is blue, the second color is green, and the third color is red:

Referring to FIG. 3, FIG. 3 is a schematic cross-sectional view at a position of BB′ in FIG. 2. The display panel includes a substrate 100 and a first electrode layer 200, a pixel definition layer 300, a light-emitting device layer 400, a second electrode layer 500, and an encapsulation layer 600, which are sequentially disposed on the substrate 100.

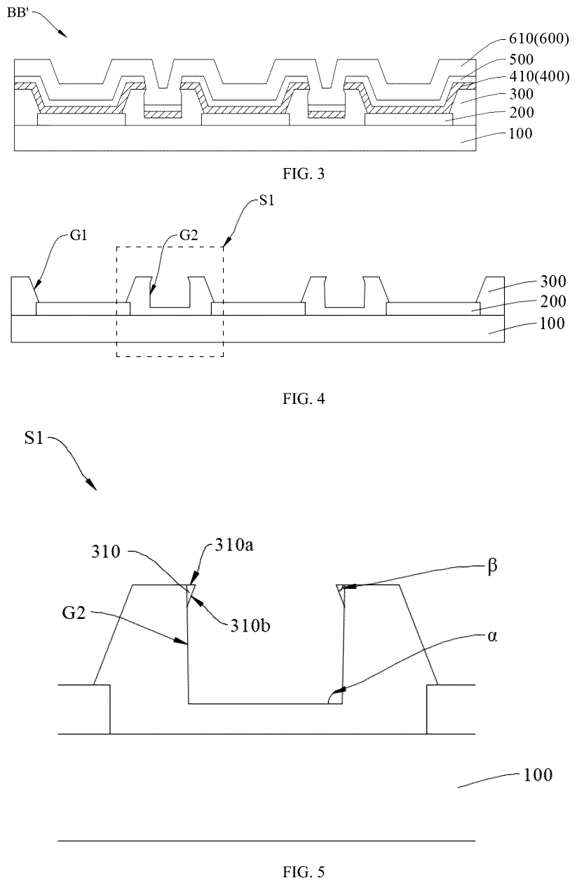

Specifically, the first electrode layer 200 includes a plurality of first electrodes provided corresponding to a plurality of the light-emitting areas A1. The pixel definition layer 300 is disposed on the substrate 100. Referring to FIG. 4, the pixel definition layer 300 includes a plurality of first grooves G1 provided corresponding to the plurality of light-emitting areas and second grooves G2 disposed in the non-light-emitting areas. Each of the first grooves G1 expose a corresponding first electrode. The light-emitting device layer 400 is disposed on the pixel definition layer 300 and the first electrode layer 200, and includes a light-emitting functional layer located in the light-emitting area A1 and a common functional layer 410 located in the light-emitting area A1 and the non-light-emitting area A2. The second electrode layer 500 is disposed on the light-emitting device layer 400. The encapsulation layer 600 is disposed on the second electrode layer 500 and includes a first encapsulation sublayer 610 disposed on the light-emitting device layer 400, and the first encapsulation sublayer 610 is disposed in the light-emitting region A1 and the non-light-emitting region A2;
The second groove G2 has a detailed structure as shown in FIG. 5, which is a partial enlarged view of a region S1 in FIG. 4. A protrusion 310 is provided at an opening of the second groove G2, and the protrusion 310 has a protruding distance which is less than or equal to one tenth of the thickness of the first encapsulation sublayer.

In the display panel provided in the embodiment of the present disclosure, the protrusion 310 is provided at the opening of the second groove G2 of the pixel definition layer 300 corresponding to the non-light-emitting area A2, when the portion of the common functional layer located in the non-light-emitting area A2 covers the second groove G2, the common functional layer is fractured at a sidewall of the second groove G2, thereby reducing the lateral leakage between adjacent light-emitting areas, and effectively avoiding the problem of poor display due to the accidental luminescence of pixels. At the same time, since the protrusion 310 has a protruding distance which is less than or equal to one tenth of the thickness of the first encapsulation sublayer, the protrusion 310 has a slight effect on the deposition of the first encapsulation sub-layer 610 at the second groove G2, and a portion of the first encapsulation sub-layer 610 located in the non-light-emitting area A2 can be continuously provided and ensure a thicker film thickness, in the region corresponding to the second groove G2. Thus, it is ensured that the encapsulation layer 600 has better encapsulation reliability. That is, by providing the protrusion 310 at the opening of the second groove G2, it is possible to effectively improve poor display due to the accidental luminescence of pixels, while ensuring better encapsulation reliability.

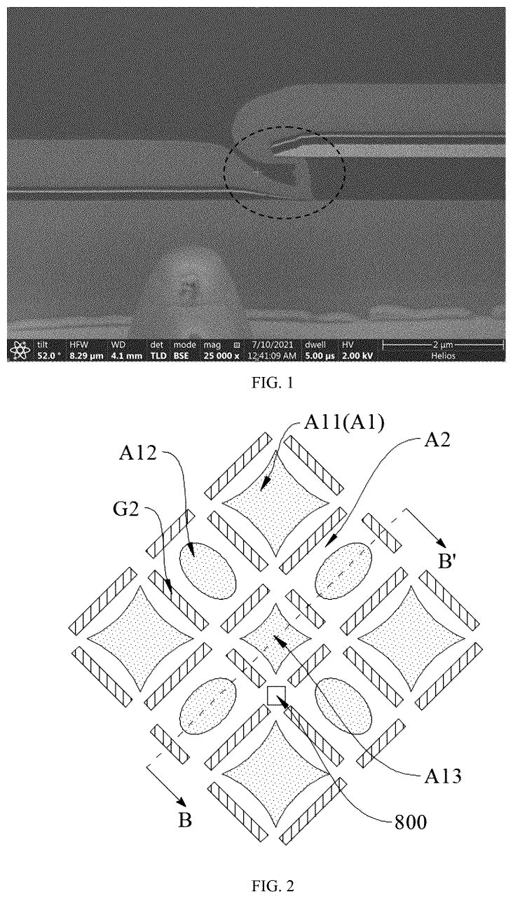

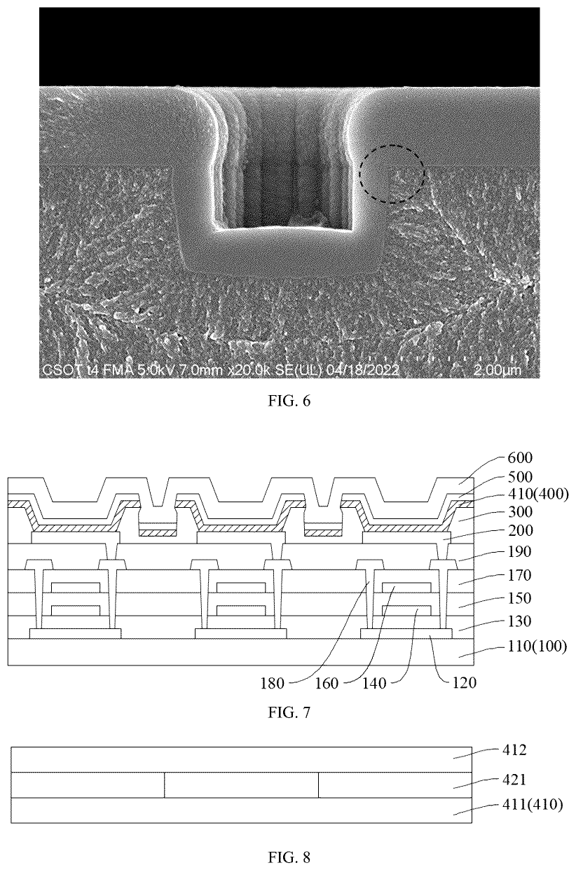

Referring to FIG. 6, in which an actual structure schematic view of the display panel according to an embodiment of the present disclosure is shown, a region indicated by a circle is a protrusion protruding toward the inside of the second groove. It can be seen that the protruding distance of the protrusion is much less than the thickness of the first encapsulation sublayer of the upper layer. At the same time, although the thickness of the first encapsulation sublayer in the region of the second groove is reduced to a certain extent compared with the thickness of the first encapsulation sublayer in the non-groove region, compared with the structure of FIG. 1, the thickness of the first encapsulation sublayer in the region of the second groove is greatly increased, and the thickness of the first encapsulation sublayer in the region of the second groove is more uniform, so that there is no inflection point where the film thickness is suddenly reduced, thereby ensuring better encapsulation reliability.

It should be noted that the protruding distance of the protrusion 310 defined above can be understood as a maximum distance in a protruding direction of the protrusion, and the protruding direction of the protrusion 310 can be any direction, for example, a horizontal direction parallel to the substrate 100 or a vertical direction perpendicular to the substrate 100 or other directions inclined with respect to the substrate 100.

The thickness of the first encapsulation sublayer 610 defined above may be understood as a thickness of the first encapsulation sublayer 610 in the non-groove region of the pixel definition layer 300.

In addition to the first encapsulation sublayer 610, the encapsulation layer 600 generally includes a second encapsulation sublayer and a third encapsulation sublayer disposed at a side of the first encapsulation sublayer 610 away from the substrate 100. The first encapsulation sublayer and the third encapsulation sublayer are inorganic encapsulation layers, and specifically may be a silicon oxide thin film or a silicon nitride thin film, and the second encapsulation sublayer is an organic encapsulation layer, so that a better encapsulation effect is achieved by such a stacked arrangement of inorganic film layer/organic film layer/inorganic film layer.

The substrate 100 is generally an array substrate. Referring to FIG. 7, the substrate 100 includes a base 110, and an active layer 120, a first insulating layer 130, a first metal layer 140, a second insulating layer 150, a second metal layer 160, a third insulating layer 170, a third metal layer 180, and a planarization layer 190 that are sequentially disposed on the base 110.

In some embodiments, on the basis that the protruding distance of the protrusion 310 is set to be less than or equal to one tenth of the thickness of the first encapsulation sublayer to ensure the encapsulation reliability, the protruding distance of the protrusion 310 should not be set to be too small in consideration of the effect of blocking the common functional layer 410, and therefore, the protruding distance of the protrusion 310 is also set to be greater than or equal to one tenth of the thickness of the common functional layer to ensure that the common functional layer 410 can be effectively fractured at the sidewall of the second groove G2 when covering the second groove G2, thereby avoiding a poor occurrence due to the accidental luminescence of pixels.

In some embodiments, the protruding distance of the protrusion 310 is in a specific range of 10 nm-100 nm, and the specific protruding distance is determined according to the actual process requirements.

In some embodiments, referring to FIG. 8, in which a specific structure of the light-emitting device layer in the display panel is shown, a first hole-transporting layer 411, a first light-emitting sublayer 421, and a first electron-transporting layer 412 are sequentially provided between the first electrode layer and the second electrode layer. The first light-emitting sublayer 421 includes a first color light-emitting function portion, a second color light-emitting function portion and a first color light-emitting function portion, which are disposed in the first grooves G1 and are disposed in the first color light-emitting area A11, the second color light-emitting area A12, and the third color light-emitting area A13, respectively, the first hole-transporting layer 411 and the first electron-transporting layer 412 are provided in both the light-emitting area A1 and the non-light-emitting area A2, and the common functional layer 410 includes the first hole-transporting layer 411 and the first electron-transporting layer 412.

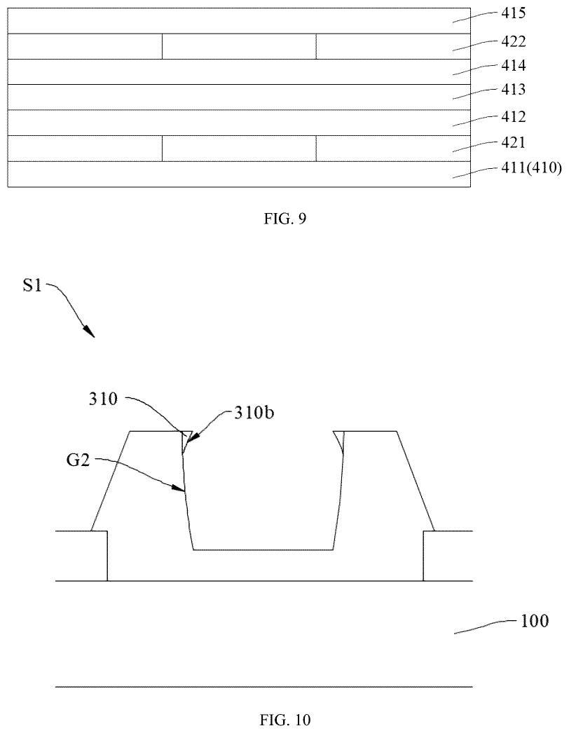

In some embodiments, a specific structure of the light-emitting device layer in the display panel is described with reference to FIG. 9. A first hole-transporting layer 411, a first light-emitting sublayer 421, a first electron-transporting layer 412, a charge-generating layer 413, a second hole-transporting layer 414, a second light-emitting sublayer 422, and a second electron-transporting layer 415 are sequentially provided between the first electrode layer and the second electrode layer. Different from the above embodiments, the light-emitting device layer in the present embodiment includes two light-emitting devices in series between the first electrode layer and the second electrode layer for any one of the light-emitting areas, and the charge-generating layer 413 is provided between the two light-emitting devices. The charge-generating layer 413 is also provided in both the light-emitting area A1 and the non-light-emitting area A2, that is, the common functional layer 410 includes the first hole-transporting layer 411, the first electron-transporting layer 412, the second hole-transporting layer 414 and the second electron-transporting layer 415. It is added that, in this series-type light-emitting device, the occurrence risk of the accidental luminescence of pixels is higher. By providing the protrusions, the common functional layer 410 including the charge-generating layer 413 is disconnected at the second groove G2, the display defect caused by the accidental luminescence of pixels in the series-type light-emitting device may be effectively improved, while also ensuring better encapsulation reliability.

In some embodiments, referring to FIG. 5, the included angle. Alpha. between the side wall of the second groove G2 and the bottom surface of the second groove is greater than or equal to 90 degrees, which facilitates deposition of the first encapsulation sublayer into a film on the side wall of the second groove G2 compared to a groove structure in which the included angle between the side wall of the groove and the bottom surface is an acute angle, so that the first encapsulation sublayer has a thicker film thickness on the side wall of the second groove G2, thereby further increasing encapsulation reliability of the encapsulation layer.

Further, an included angle a between the sidewall of the second groove and a bottom surface of the second groove is greater than 90 degree and less than 100 degree. That is, the second sidewall G22 is disposed so as to be approximately perpendicular to the substrate 100, so that the second sidewall G22 is steeper to further enhance the blocking ability of the second groove G2 to the common functional layer 410.

In some embodiments, one end of the protrusion 310 is in contact with a sidewall of the opening of the second groove G2, and the other end thereof extends into the second groove G2. That is, the protrusion 310 protrudes toward the inside of the second groove G2, and the protrusion 310 causes the opening of the second groove G2 to form an undercut opening which has a good blocking capability for the common functional layer 410, so that the common functional layer 410 is broken at the second groove G2.

In conjunction with FIGS. 2 and 5, the protrusion 310 may be understood as an annular structure extending from the sidewall of the second groove G2 to the inside of the sidewall of the second groove G2 around the opening of the second groove G2.

In some embodiments, referring to FIG. 5, the protrusion 310 has a first side surface 310a that is away from the substrate 100, the first side surface 310a is aligned with a side surface of the pixel definition layer 300 away from the substrate 100. The protrusion 310 of this structure is formed together with the pixel definition layer 300 by the same process. Specifically, when the second groove G2 is formed by etching, a barrier layer composed of a metal or a metal oxide is provided, and the protrusion 310 and the pixel definition layer 300 are obtained by a certain blocking effect on the plasma in an open region of the second groove G2. For more detailed steps and process principles, reference may be made to the following description of embodiments of the manufacturing method of the display panel.

In some embodiments, referring to FIG. 5, the protrusion 310 has a second side surface 310b connected to an end of the first side surface 310a close to the inside of the second groove, and the second side surface 310b and the first side surface 310a have an included angle B, which is an acute angle. Compared with the case where the included angle between the second side surface 310b and the first side surface 310a is an obtuse angle, under the premise that the protrusion 310 of this structure has a certain protruding distance, the protrusion 310 has a smaller influence on the deposition of the first encapsulation sublayer 610 at the position of the second groove G2, and the first encapsulation sublayer 610 has a thicker film thickness at the position corresponding to the second groove G2, which is more favorable for ensuring the encapsulation reliability of the encapsulation layer 600.

Further, the included angle β may be specifically set to 20 degrees to 70 degrees. When the included angle β is too large, the second groove G2 is insufficient in its ability to block the common functional layer 410, and when the included angle. β is too small, the protrusion 310 is at risk of collapse. Therefore, the included angle β is set to 20 degrees to 70 degrees to avoid the aforementioned problems.

In some embodiments, one end of the second side surface 310b is connected to the first side surface 310a, and another end of the second side surface 310b is directly connected to the side wall of the second groove G2, thereby avoiding the formation of a step structure at the connection between the second side surface 310b and the sidewall of the second groove G2 and affecting the deposition of the first encapsulation sublayer 610 into a film in the second groove G2, thereby facilitating the thicker film thickness of the first encapsulation sublayer 610 in the region corresponding to the second groove G2 to ensure the encapsulation reliability of the encapsulation layer 600.

In some embodiments, a connection angle between the second side surface 310b and the sidewall of the second groove G2 is an obtuse angle, i.e., the corner at which the second side surface 310b is connected to the sidewall of the second groove G2 is relatively gentle, facilitating the deposition of the first encapsulation sublayer on the sidewall of the second groove G2 to further ensure the film thickness of the first encapsulation sublayer in the region of the second groove G2, thereby increasing the encapsulation reliability.

In some embodiments, referring to FIG. 10, the second side surface 310b of the protrusion 310 and the sidewall of the second groove G2 are curved in a curve toward the inside of the second groove G2, so that the connection angle between the second side surface 310b of the protrusion 310 and the sidewall of the second groove G2 is an arc angle. Therefore, the deposition of the first encapsulation sublayer on the sidewall of the second groove G2 is facilitated, thereby further ensuring the film layer thickness of the first encapsulation sublayer in the region of the second groove G2 so as to improve encapsulation reliability.

In some embodiments, the depth of the second groove G2 is less than or equal to the maximum thickness of the pixel definition layer 300, and when the depth of the second groove G2 is less than the maximum thickness of the pixel definition layer 300, the second groove G2 only partially penetrates through the pixel definition layer 300, so as to avoid a problem of causing damage to the first electrode layer 200 of the lower layer when the second groove G2 is formed by etching to cause poor display.

In some embodiments, the depth of the second groove G2 is 1.3 μm-4 μm.

In some embodiments, while the second groove G2 blocks the common functional layer 410, the second electrode layer 500 located on the common functional layer 410 is also at risk of being blocked by the second groove G2. Although the risk of poor display caused by the separation of the second electrode layer 500 in the second groove G2 can be reduced by adjusting the preparation process parameters (such as the size of the evaporation angle, etc.) of the second electrode layer 500, it is difficult to completely circumvent this problem by adjusting the preparation process parameters. Based on this, the second grooves G2 are provided at intervals in the non-light-emitting area A2. Specifically, referring to FIG. 2, the pixel definition layer includes a plurality of second grooves G2, the plurality of second grooves G2 are provided at intervals in the non-light-emitting area A2, and the spaced regions of the two adjacent second grooves G2 serve as regions for ensuring the connection of the second electrode layer 500, whereby the problem of poor display caused by the separation of portions of the second electrode layer 500 between the adjacent light-emitting areas A1 can be completely avoided.

It is further noted that, in this arrangement, although the common functional layer 410 is still connected in the spaced region between the adjacent second grooves G2, compared with a structure in which the second groove G2 is not provided, the communication channel between the portions of the common functional layer 410 corresponding to the two adjacent light-emitting areas A1 is narrowed and the communication path is extended, thereby greatly reducing the lateral leakage current in the common functional layer 410 between the two adjacent light-emitting areas A1. By setting the shape of the second groove G2, the size of the lateral leakage current is kept less than or equal to the target value, it is possible to avoid poor display due to the accidental luminescence of pixels.

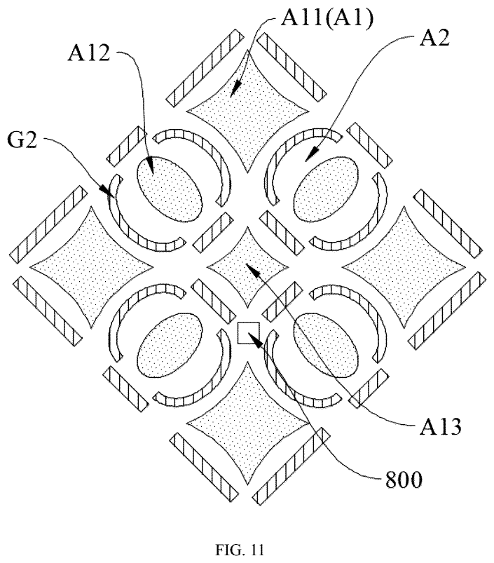

In some embodiments, the size of the lateral leakage current is kept less than or equal to the target value by setting the shape of the second groove G2, which may be achieved by extending at least a part of the second groove along an edge of an adjacent light-emitting area, as will be exemplified below in connection with FIG. 11. For example, if the second color light-emitting area A12 is elliptical, the second groove G2 between the second color light-emitting area A12 and the first color light-emitting area A11 is provided as a curved groove extending along an edge of an adjacent second color light-emitting area A12, so that the second groove G2 between the second color light-emitting area A12 and the first color light-emitting area A11 extends further in a direction toward the second groove G2 between the second color light-emitting area A12 and the third color light-emitting area A13, thereby reducing the spacing between the two second grooves G2, narrowing the communication channel of the common functional layer 410 here, and keeping the size of the lateral leakage flow here less than or equal to the target value.

Here is only an exemplary description according to the specific pixel arrangement, in practical applications, according to the specific pixel arrangement structure, the second groove G2 may be a corrugated groove, a zigzag groove, or the like, in addition to the above-mentioned curved groove.

In some embodiments, the capability of blocking the common functional layer 410 may be further enhanced by providing a plurality of the second grooves G2 between two adjacent light-emitting areas A1. Specifically, referring to FIG. 12, a plurality of the second grooves G2 are provided between the two adjacent light-emitting areas A1, and the plurality of second grooves G2 are arranged at intervals along a direction from a center of one light-emitting area to a center of another light-emitting area A1. For example, two second grooves G2 are provided between the two adjacent light-emitting areas A1, which are illustratively shown in the figure, so that when one of the second grooves G2 fails to completely block the common functional layer 410, it is ensured that the common functional layer 410 is completely blocked in an region in which the second grooves G2 are provided between the two adjacent light-emitting areas A1 by increasing the number of the second grooves G2 between the two adjacent light-emitting areas A1, thereby avoiding a poor display due to the accidental luminescence of pixels.

In some embodiments, referring to FIG. 2, a support post 800 is also generally provided in the display panel for supporting the mask plate during the evaporation process. In order to avoid collapse of the support post 800 caused by the second groove G2, the second groove G2 is provided away from the support post 800.

It will be appreciated that the arrangement of the second grooves is set in accordance with the actual pixel arrangement, and the above embodiment will be described with reference to a specific pixel arrangement. In order to further clearly show the arrangement of the second grooves G2, the following description will be made in accordance with another pixel arrangement.

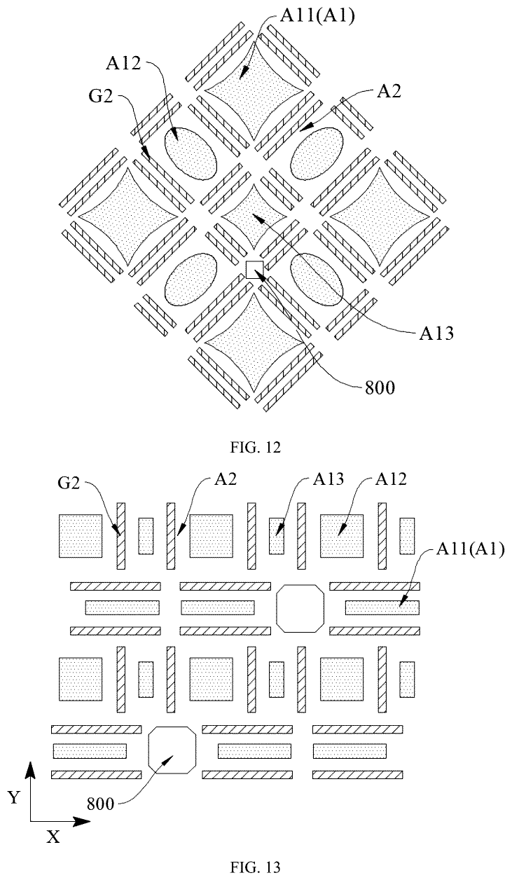

In some embodiments, referring to FIG. 13, the display area also includes a plurality of light-emitting areas A1 arranged at intervals and a non-light-emitting area A2 disposed between the plurality of light-emitting areas A1, the light-emitting areas A1 include a first color light-emitting area A11, a second color light-emitting area A12, and a third color light-emitting area A13. The shapes and arrangement of the first color light-emitting area A11, the second color light-emitting area A12, and the third color light-emitting area A13 are different from that of the foregoing embodiments. Each of the light-emitting areas A1 is rectangular, and the light-emitting areas A1 are arranged at intervals along a first direction X or a second direction Y. Based on this, the second grooves G2 each having a long rectangular shape extending in the first direction X or the second direction Y are correspondingly disposed in the non-light-emitting area A2. Specifically, the second groove G2 having the long rectangular shape extending in the second direction Y is disposed between the second color light-emitting area A12 and the third color light-emitting area A13 which are adjacent to each other., and the second groove G2 having the long rectangular shape extending in the first direction X is provided between the first color light-emitting area A11 and the second color light-emitting area A12 and the third color light-emitting area A13 which are adjacent to the first color light-emitting area A11, while the second groove G2 is provided to avoid the region of the support post 800.

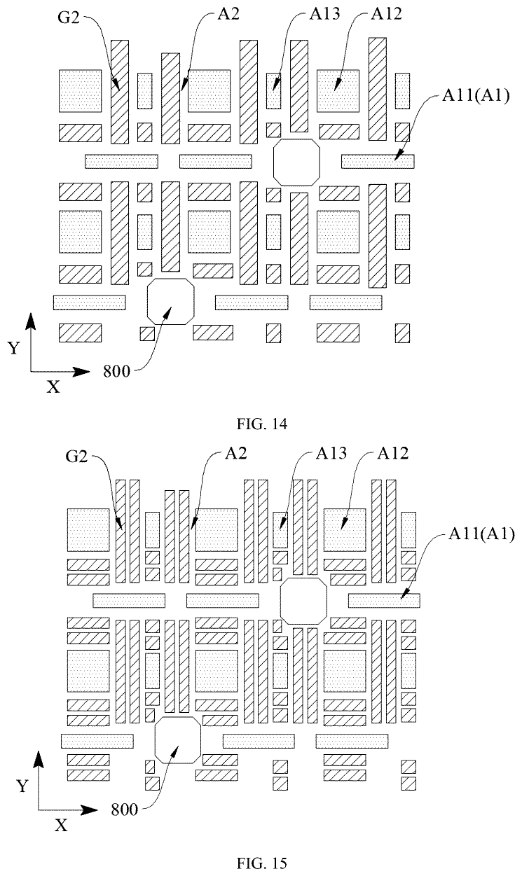

In some embodiments, referring to FIG. 14, the display panel provided in the previous embodiment is substantially similar to that provided in the previous embodiment, except that the arrangement of various second grooves G2 is fine-tuned, and a second groove G2 with a square shape is added to a vacant area, so that four of the second grooves G2 are correspondingly provided around each of the second color light-emitting areas A12 or each of the third color light-emitting areas A13, thereby further reducing the spacing between two adjacent second grooves G2, and narrowing the communication channel of the common functional layer herein, which further reduces the size of the lateral leakage current therein.

In some embodiments, referring to FIG. 15, it is substantially similar to the display panel provided in the previous embodiment, except that each of the second grooves in the previous embodiment is adjusted to two second grooves G2 spaced apart from each other to further enhance the ability of blocking the common functional layer.

In some embodiments, the arrangement range of the second groove G2 is located within the flat area of the pixel definition layer 300, so as to avoid damage to the original morphology of the pixel definition layer 300, that is, there is a certain distance between the first groove G1 and the second groove G2 which are adjacent to each other, which avoids the problem that the second groove G2 affects the original morphology of the first groove G1 and causes other display defects.

In some embodiments, the second groove G2 may be provided only between two adjacent light-emitting areas A1, and an area located outside the light-emitting areas A1 at the edge does not need to be provided with the second groove G2.

In the above-mentioned embodiments, the description of each embodiment has its own emphasis, and parts not described in detail in a certain embodiment may be referred to the above detailed description for other embodiments, and details are not described herein again.

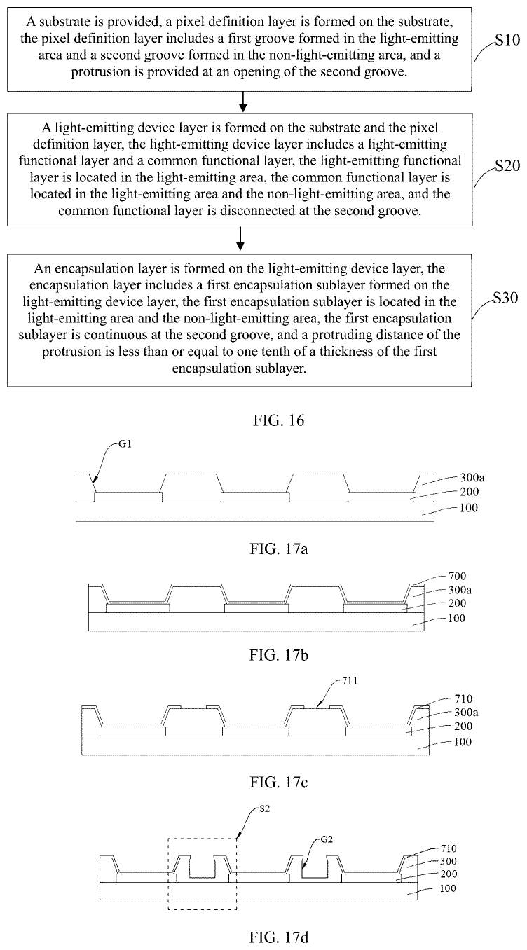

Another embodiment of the present disclosure further provides a specific method of manufacturing the display panel in the above embodiment. Referring to FIG. 16, the manufacturing method specifically includes the following steps.

At step S10, a substrate is provided, a pixel definition layer is formed on the substrate, the pixel definition layer includes a first groove formed in the light-emitting area and a second groove formed in the non-light-emitting area, and a protrusion is provided at an opening of the second groove.

At step S20, a light-emitting device layer is formed on the substrate and the pixel definition layer, the light-emitting device layer includes a light-emitting functional layer and a common functional layer, the light-emitting functional layer is located in the light-emitting area, the common functional layer is located in the light-emitting area and the non-light-emitting area, and the common functional layer is disconnected at the second groove.

At step S30, an encapsulation layer is formed on the light-emitting device layer, the encapsulation layer includes a first encapsulation sublayer formed on the light-emitting device layer, the first encapsulation sublayer is located in the light-emitting area and the non-light-emitting area, the first encapsulation sublayer is continuous at the second groove, and a protruding distance of the protrusion is less than or equal to one tenth of a thickness of the first encapsulation sublayer.

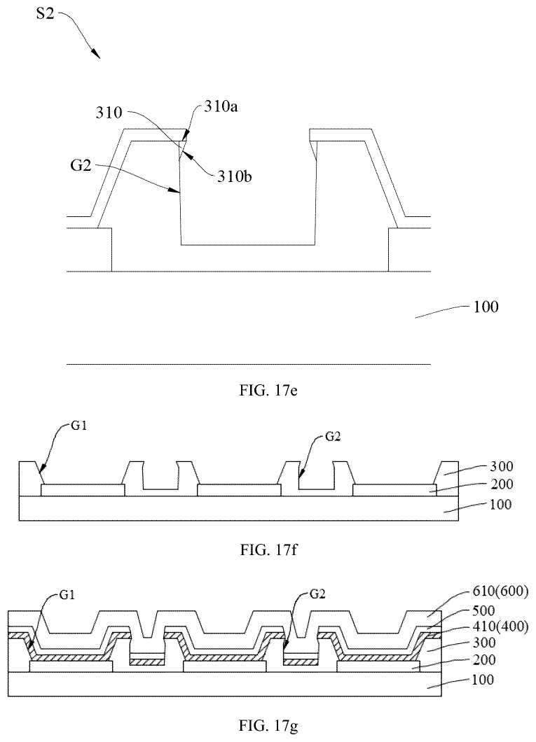

The method of manufacturing the display panel will be described in detail below with reference to FIGS. 17a-17g:

Referring to FIG. 17a, there is provided a substrate 100 on which a first electrode layer 200 including a plurality of first electrodes provided corresponding to a plurality of light-emitting areas is formed.

A first organic film layer 300a is formed on the first electrode layer 200 and the substrate 100, the first organic film layer 300a includes a plurality of first grooves G1 corresponding to the plurality of light-emitting areas, one of the first grooves G1 exposes a corresponding one of the first electrodes, a material of the first organic film layer 300a is an organic photoresist, and the first grooves G1 are formed by an exposure development process under the shielding of the corresponding photomask.

Referring to FIG. 17b, a barrier film 700 is formed on the first organic film layer 300a and the first electrode layer 200, and a material of the barrier film 700 is a metal or a metal oxide, and may be, for example, indium tin oxide, indium zinc oxide, copper, or the like, and a thickness of the barrier film is determined according to a design, for example, a thickness of the barrier film layer is 5 nm, 10 nm, 15 nm, 20 nm, or the like.

Referring to FIG. 17c, the barrier film 700 is patterned to form a barrier layer 710, and the barrier layer 710 includes an opening 711 formed in a predetermined region of the non-light-emitting area.

Referring to FIG. 17d, a pixel definition layer 300 is formed by dry etching the first organic film layer 300a under the barrier of the barrier layer 710. In the dry etching process, and an area of the first organic film layer 300a exposed by the opening 711 is etched under the bombardment of the plasma to form a second groove G2. The shape of the second groove G2 is shown in FIG. 17e which is an enlarged structural diagram of a region S2 in FIG. 17d. At the opening of the second groove G2, a protrusion 310 protruding toward the inside of the second groove G2 is formed.

Referring to FIG. 17f, the barrier layer 710 is removed, specifically, the barrier layer can be dissolved and removed by a wet etching process using a corresponding etching acid. It is further noted that the first electrode layer 200 at lower side of the barrier layer 710 is generally a stacked structure of an indium tin oxide layer/a silver layer/an indium tin oxide layer, the indium tin oxide layer in the first electrode layer 200 is crystalline indium tin oxide after thermal annealing, and when the material of the barrier layer 710 is indium tin oxide, it is specifically amorphous indium tin oxide, so that when the barrier layer 710 is removed, the etching acid used does not cause damage to the surface layer of the indium tin oxide layer in the first electrode layer 200.

Referring to FIG. 17g, a light-emitting device layer 400, a second electrode layer 500, and an encapsulation layer 600 are sequentially formed on the first electrode layer 200 and the pixel definition layer 300, the light-emitting device layer includes a light-emitting functional layer and a common functional layer 410, the light-emitting functional layer is located in the light-emitting area A1, and the common functional layer 410 is located in the light-emitting area A1 and the non-light-emitting area A2. The encapsulation layer 600 includes a first encapsulation sublayer 610 formed on the light-emitting device layer 400, the first encapsulation sub-layer 610 is located in the light-emitting area A1 and the non-light-emitting area A2, the common functional layer 410 is disconnected at the second groove G2, the first encapsulation sublayer 610 is continuous at the second groove G2, and the protruding distance of the protrusion 310 is less than or equal to one tenth of the thickness of the first encapsulation sublayer 610, that is, the manufacturing of the display panel is completed.

Specifically, in the process of forming the second groove G2, a certain amount of lateral etching is also performed while the plasma performs the longitudinal etching to form a groove. Since the barrier layer 710 is provided at the peripheral side of the opening 711, the barrier layer 710 has a certain shielding effect on the plasma during the etching, so that in a direction perpendicular to the substrate 100, the degree of lateral etching near the barrier layer 710 is weaker than the degree of lateral etching at a distance from the barrier layer 710. Thus, the protrusion 310 is formed at the opening of the second groove G2, the protrusion 310 has a first side surface 310a that is aligned with a side surface of the pixel definition layer 300 away from the substrate 100, and a second side surface 310b connected to the first side surface 310a, and the included angle between the second side surface 310b and the first side surface 310a is an acute angle.

However, as the distance from the barrier layer 710 becomes farther and farther, the barrier effect of the barrier layer 710 to the lateral etching becomes weaker and weaker until it disappears, so that one end of the second side surface 310b is connected to one end of the first side surface 310a close to the inside of the second groove, and another end of the second side surface 310b extends toward the sidewall of the second groove G2 and is directly connected to the sidewall of the second groove G2.

In addition, the reason that the included angle between the sidewall of the second groove G2 and the bottom surface of the second groove G2 is greater than 90 degrees is that the region closer to the upper side is etched laterally for a longer time, but in order to enhance the blocking ability of the second groove G2 to the common functional layer 410, the etching parameters can be adjusted so that the inclination degree of the sidewall of the second groove G2 is as small as possible or the sidewall of the second groove G2 is nearly perpendicular to the substrate 100.

Further, due to the limited ability of the barrier layer 710 to block the plasma, the protruding distance of the protrusion 310 formed may be made very small, and further, by adjusting the etching parameters, the protruding distance of the protrusion 310 is finally made to be less than or equal to one tenth of the thickness of the first encapsulation sublayer;
In the method for manufacturing the display panel according to the present embodiment, the protrusion 310 is formed at the opening of the second groove G2 by the above-mentioned specific process, so that when the portion of the common functional layer located in the non-light-emitting area A2 covers the second groove G2, the common functional layer is broken at the sidewall of the second groove G2. Therefore, the lateral leakage current between adjacent light-emitting areas is reduced, and the problem of poor display due to the accidental luminescence of pixels is effectively avoided. At the same time, since the protrusion 310 has a protruding distance of less than or equal to one tenth of the thickness of the first encapsulation sublayer, the protrusion 310 has little influence on the deposition of the first encapsulation sublayer 610 at the second groove G2, a portion of the first encapsulation sublayer 610 located in the non-light-emitting area A2 may still ensure a thicker film thickness in a region corresponding to the second groove G2, thereby ensuring that the encapsulation layer 600 has better encapsulation reliability. That is, by forming the second groove G2, poor display due to the accidental luminescence of pixels may be effectively improved, and better encapsulation reliability may be ensured.

It is further noted that the groove structure in the present display panel is generally formed by the etching process using a patterned photoresist layer as a barrier layer. However, the photoresist layer is inevitably etched away from a portion during the etching process, so as to not play a better barrier effect on the lateral etching. In the present embodiment, by using a barrier layer formed of a metal or a metal oxide, the barrier layer is not sensitive to the plasma for etching the pixel definition layer formed of the photoresist material, and is substantially not interact with and removed by the plasma during the etching process, so that a better barrier effect on the lateral etching may be achieved, and the protrusion having a special size is formed at the opening of the second groove.

Another embodiment of the present disclosure further provides a display device including a display panel provided in the above embodiment, the display device includes, but not limited to a mobile phone, a smart watch, a tablet computer, a notebook computer, a television, and the like.

A display panel and a display device provided by the embodiment of the present disclosure are described in detail above. The principles and implementations of the present disclosure have been described with reference to specific embodiments, and the description of the above embodiments is merely intended to aid in the understanding the method of the present disclosure and its core idea. At the same time, changes may be made by those skilled in the art to both the specific implementations and the scope of application in accordance with the teachings of the present disclosure. In view of the foregoing, the content of the present specification should not be construed as limiting the disclosure.

What is claimed is:

1. A display panel comprising a plurality of light-emitting areas spaced apart from each other and a non-light-emitting area between the light-emitting areas, wherein the display panel comprises:
a substrate;
a pixel definition layer disposed on the substrate, and comprising one or more first grooves corresponding to the light-emitting areas and one or more second grooves disposed in the non-light-emitting region;
a light-emitting device layer disposed on the pixel definition layer and the substrate, comprising a light-emitting functional layer and a common functional layer, wherein the light-emitting functional layer is located in the light-emitting areas and the common functional layer is located in the light-emitting areas and the non-light-emitting area; and
an encapsulation layer disposed on the light-emitting device layer and comprising a first encapsulation sublayer disposed on the light-emitting device layer, the first encapsulation sublayer being located in the light-emitting areas and the non-light-emitting area;
wherein a protrusion is provided at an opening of each of the second grooves, the common functional layer is disconnected at the second grooves, the first encapsulation sublayer is provided continuously at the second grooves, and a protruding distance of the protrusion is less than or equal to one tenth of a thickness of the first encapsulation sublayer.

2. The display panel according to claim 1, wherein an included angle between a sidewall and a bottom surface of each of the second grooves is greater than or equal to 90 degrees.

3. The display panel according to claim 2, wherein one end of the protrusion is in contact with a sidewall at an opening of a corresponding second groove of the second grooves, and another end of the protrusion extends toward inside of the corresponding second groove.

4. The display panel according to claim 3, wherein the protrusion has a first side surface away from the substrate, and the first side surface is aligned with a side surface of the pixel definition layer away from the substrate.

5. The display panel according to claim 4, wherein the protrusion has a second side surface connected to one end of the first side surface close to the inside of the corresponding second groove, and an included angle between the second side surface and the first side surface is an acute angle.

6. The display panel according to claim 2, wherein the included angle between the sidewall and the bottom surface of each of the second grooves is greater than 90 degrees and less than 100 degrees, and a depth of each of the second groove is less than or equal to a maximum thickness of the pixel definition layer.

7. The display panel according to claim 1, wherein the protruding distance of the protrusion is greater than or equal to one tenth of a thickness of the common functional layer.

8. The display panel according to claim 1, wherein the light-emitting functional layer includes a first light-emitting sublayer and a second light-emitting sublayer, and the common functional layer includes a charge-generating layer disposed between the first light-emitting sublayer and the second light-emitting sublayer; and
the charge-generating layer is disconnected at the second grooves.

9. The display panel according to claim 1, wherein there are a plurality of second grooves provided between two adjacent light-emitting areas, and at least a portion of the second grooves are provided along an edge of one of the adjacent light-emitting areas.

10. The display panel according to claim 9, wherein the second grooves are curved grooves, corrugated grooves, or zigzag grooves.

11. The display panel according to claim 9, wherein there are a plurality of second grooves arranged at intervals along a direction from a center of one of the light-emitting areas toward a center of another of the light-emitting areas.

12. The display panel according to claim 9, wherein the light-emitting areas are each rectangular and are arranged at intervals in a first direction or a second direction, and the second grooves are each long rectangle correspondingly extending in the first direction or the second direction.

13. The display panel according to claim 12, wherein there are two second grooves provided at intervals between the two adjacent light-emitting areas, the two second grooves are both long rectangles extending in the first direction.

14. A display device, wherein the display device comprises a display panel, the display panel comprising:
a substrate;
a pixel definition layer disposed on the substrate, and comprising one or more first grooves corresponding to the light-emitting areas and one or more second grooves disposed in the non-light-emitting region;
a light-emitting device layer disposed on the pixel definition layer and the substrate, comprising a light-emitting functional layer and a common functional layer, wherein the light-emitting functional layer is located in the light-emitting areas and the common functional layer is located in the light-emitting areas and the non-light-emitting area; and
an encapsulation layer disposed on the light-emitting device layer and comprising a first encapsulation sublayer disposed on the light-emitting device layer, the first encapsulation sublayer being located in the light-emitting areas and the non-light-emitting area;
wherein a protrusion is provided at an opening of each of the second grooves, the common functional layer is disconnected at the second grooves, the first encapsulation sublayer is provided continuously at the second grooves, and a protruding distance of the protrusion is less than or equal to one tenth of a thickness of the first encapsulation sublayer.

15. The display device according to claim 14, wherein an included angle between a sidewall and a bottom surface of each of the second grooves is greater than or equal to 90 degrees.

16. The display device according to claim 15, wherein one end of the protrusion is in contact with a sidewall at an opening of a corresponding second groove of the second grooves, and another end of the protrusion extends toward inside of the corresponding second groove.

17. The display device according to claim 16, wherein the protrusion has a first side surface away from the substrate, and the first side surface is aligned with a side surface of the pixel definition layer away from the substrate.

18. The display device according to claim 17, wherein the protrusion has a second side surface connected to one end of the first side surface close to the inside of the corresponding second groove, and an included angle between the second side surface and the first side surface is an acute angle.

19. The display device according to claim 15, wherein the included angle between the sidewall and the bottom surface of each of the second grooves is greater than 90 degrees and less than 100 degrees, and a depth of each of the second groove is less than or equal to a maximum thickness of the pixel definition layer.

20. The display device according to claim 14, wherein the protruding distance of the protrusion is greater than or equal to one tenth of a thickness of the common functional layer.
